(19) United States
(12) Patent Application Publication
(10) Pub. No.: US 2026/0114055 A1
(43) Pub. Date: Apr. 23, 2026

(54) PHOTOELECTRIC TRANSDUCER

(71) Applicant: MICRO SIGNAL Co., Ltd., Kyoto (JP)

(72) Inventors: Kunihiro WATANABE, Kyoto (JP); Takato WATANABE, Kyoto (JP)

(21) Appl. No.: 19/361,890

(22) Filed: Oct. 17, 2025

(30) Foreign Application Priority Data
Oct. 17, 2024 (JP) 2024-181968
Oct. 2, 2025 (JP) 2025-166012

(51) Int. Cl. H10F 30/223

(52) U.S. Cl. CPC H10F 30/223

(57) ABSTRACT

The photoelectric transducer comprises a first conductivity type semiconductor layer, a low-concentration impurity semiconductor layer formed on the semiconductor layer and having a lower impurity concentration than the semiconductor layer, and a high-concentration impurity semiconductor region of a second conductivity type, formed on the surface layer of the low-concentration impurity semiconductor layer, having a higher impurity concentration than the low-concentration impurity semiconductor layer and being different from the first conductivity type. The high-concentration impurity semiconductor region is linear and has substantially no width in a direction perpendicular to both its length direction and the thickness direction of the low-concentration impurity semiconductor layer.

### BACKGROUND OF THE INVENTION

### Technical Field

The present invention relates to a photoelectric transducer.

### Description of the Related Art

Photodiodes, which transduce light into electrical signals, are widely known as photoelectric transducers. PIN photodiodes, a type of photodiode, have excellent high-speed response, high sensitivity, and low dark current. Therefore, PIN photodiodes are widely used in devices such as remote controls and optical communication equipment.

FIG. 16 is a schematic cross-sectional view illustrating the structure of a conventional PIN photodiode.

In a conventional PIN photodiode, an intrinsic layer (i-layer) 102 is formed on a p-type substrate 101. An n+-type region 103 is formed on the surface layer of the i-layer 102. When the cathode 104 and anode 105 of the PIN photodiode are connected to high and low potentials, respectively, and a reverse bias is applied to the PIN photodiode, a depletion layer spreads from the junction between the n+-type region 103 and the i-layer 102 into the i-layer 102. When light is incident on the PIN photodiode, electrons in the valence band are excited into the conduction band, leaving holes in the valence band. This generates carriers (electrons and holes) primarily in the depletion layer. Due to the internal electric field, electrons migrate into the neutral region of the n+-type region 103, while holes migrate into the neutral region of the p-type substrate 101. For example, when a load resistor is connected to the anode 105, current flows through the load resistor, generating a voltage across its terminals. The voltage generated across the load resistor terminals is amplified by the amplifier, and this amplified voltage is extracted as an electrical signal.

The response speed of a PIN photodiode is determined by the following three elements t1, t2, and t3.
(1) Time constant t1 in the electronic circuit including the PIN photodiode and load resistor
(2) The time t2 required for the diffusion of carriers generated outside the depletion layer
(3) The time t3 required for carriers to travel through the depletion layer

The response speed of the PIN photodiode can be improved by reducing the values of each element t1, t2, and t3. The time constant t1 is proportional to the product of the inter-terminal capacitance of the PIN photodiode and the resistance value of the load resistor. Improvements in the response speed of the PIN photodiode are often constrained by the time constant t1. Therefore, reducing the inter-terminal capacitance of the PIN photodiode to decrease the time constant t1 is the most effective means for improving the response speed of the PIN photodiode.

### SUMMARY OF THE INVENTION

The objective of the present invention is to provide a photoelectric transducer capable of reducing the inter-terminal capacitance.

To achieve the aforementioned objective, the photoelectric transducer according to one aspect of the present invention includes a first conductivity type semiconductor layer, a low-concentration impurity semiconductor layer formed on the first conductivity type semiconductor layer, and a high-concentration impurity semiconductor region formed in the surface layer of the low-concentration impurity semiconductor layer. The low-concentration impurity semiconductor layer has a lower impurity concentration than the first conductivity type semiconductor layer. The high-concentration impurity semiconductor region has a second conductivity type different from the first conductivity type. The high-concentration impurity semiconductor region has a higher impurity concentration than the low-concentration impurity semiconductor layer. The high-concentration impurity semiconductor region is linear and has substantially no width in a width direction, which is orthogonal to both the length direction of the high-concentration impurity semiconductor region and the thickness direction of the low-concentration impurity semiconductor layer.

According to this configuration, the low-concentration impurity semiconductor layer, having the lower impurity concentration than the first conductivity type semiconductor layer, is formed on the first conductivity type semiconductor layer. A high-concentration impurity semiconductor region of the second conductivity type is provided in the surface region of the low-concentration impurity semiconductor layer. The high-concentration impurity semiconductor region is formed linearly with substantially no width.

In conventional photoelectric transducers (PIN photodiodes), a high-concentration impurity semiconductor region (corresponding to the n+-type region 103 shown in FIG. 16) is formed over a wide area in a planar manner on the surface layer of the low-concentration impurity semiconductor layer (corresponding to the i-layer 102 shown in FIG. 16). In contrast, in the photoelectric transducer according to the present invention, the high-concentration impurity semiconductor region is formed as a line having substantially no width in the surface layer of the low-concentration impurity semiconductor layer. Consequently, the photoelectric transducer according to the present invention can achieve a smaller junction capacitance than conventional photoelectric transducers, thereby reducing the inter-terminal capacitance. This results in an improved response speed of the photoelectric transducer.

In the photoelectric transducer, a light-receiving area is provided to accept light from outside into the low-concentration impurity semiconductor layer. The photoelectric transducer may further include an antireflection coating. The antireflection coating is formed on the light-receiving area and contacts the surface of the low-concentration impurity semiconductor layer.

According to this configuration, the antireflection film contacts the surface of the low-concentration impurity semiconductor layer within the light-receiving area. No electrodes (a wiring connected to the high-concentration impurity semiconductor region) or insulating films, etc. are formed between the surface of the low-concentration impurity semiconductor layer and the antireflection film. Therefore, light interference between the antireflection film and the low-concentration impurity semiconductor layer can be prevented.

The photoelectric transducer may further include a first conductive layer. The first conductive layer is formed above the low-concentration impurity semiconductor layer. The first conductive layer is opposite at least a portion of the high concentration impurity semiconductor region in the thickness direction. The first conductive layer may extend in the length direction and be connected to a fixed potential.

This configuration allows electromagnetic noise entering from outside toward the high-concentration impurity semiconductor region to be blocked by the first conductive layer. Consequently, it is possible to prevent external electromagnetic noise from reaching the high-concentration impurity semiconductor region, thereby eliminating adverse effects caused by electromagnetic noise.

The photoelectric transducer may further include a plurality of second conductive layers. The plurality of second conductive layers are formed above the low-concentration impurity semiconductor layer. The plurality of second conductive layers are opposed in the thickness direction to different portions of the high concentration impurity semiconductor regions. The plurality of second conductive layers may each extend in the length direction and be connected to a fixed potential.

With this configuration, even if electromagnetic noise enters from the outside toward the high-concentration impurity semiconductor region, that electromagnetic noise can be blocked by the first conductive layer or the second conductive layer. Therefore, it is further possible to prevent external electromagnetic noise from reaching the high-concentration impurity semiconductor region, thereby eliminating adverse effects caused by electromagnetic noise.

The photoelectric transducer may have a configuration where an interlayer film is formed between the first conductive layer and the second conductive layer, and a via extending in the length direction penetrates the interlayer film in the thickness direction, with the via connecting the first conductive layer and the second conductive layer.

In this configuration, even if electromagnetic noise enters from the outside in a direction intersecting the thickness toward the high-concentration impurity semiconductor region, the electromagnetic noise can be blocked by the first conductive layer, the second conductive layer, or the via. Therefore, it prevents external electromagnetic noise from reaching the high-concentration impurity semiconductor region and eliminates adverse effects caused by electromagnetic noise.

The photoelectric transducer may have a configuration where an interlayer film is formed between the low-concentration impurity semiconductor layer and the first conductive layer, and two vias extending in the length direction each penetrate the interlayer film in the thickness direction, with the two vias connecting the first conductive layer and the low-concentration impurity semiconductor layer. In this configuration, a first conductive type contact region with a higher impurity concentration than the low-concentration impurity semiconductor layer is formed on the surface layer of the low-concentration impurity semiconductor layer. The contact regions are provided at positions spaced apart from one side and the other side in the width direction relative to the high-concentration impurity semiconductor region, The two vias are connected to the contact regions on one side and the other side in the width direction relative to the high-concentration impurity semiconductor region, respectively.

This configuration allows electromagnetic noise entering from the outside toward the high-concentration impurity semiconductor region in the thickness direction to be blocked by the first conductive layer. Furthermore, even if electromagnetic noise enters from the outside toward the high-concentration impurity semiconductor region in a direction intersecting the thickness direction, that electromagnetic noise can be blocked by the first conductive layer or the via. Therefore, it is possible to prevent external electromagnetic noise from reaching the high-concentration impurity semiconductor region and eliminate adverse effects caused by electromagnetic noise.

The photoelectric transducer may have a configuration where a first conductive type semiconductor region for fixed potential connection is formed in the surface layer of the low-concentration impurity semiconductor layer. In this configuration, the semiconductor region for fixed potential connection may be spaced apart from the high-concentration impurity semiconductor region in the width direction, extend in the length direction, and be connected to a fixed potential.

In this configuration, even if electromagnetic noise enters from outside into the region adjacent in the width direction to the high-concentration impurity semiconductor region, that electromagnetic noise can be blocked by the fixed-potential connection semiconductor region. Therefore, it is possible to prevent external electromagnetic noise from reaching the high-concentration impurity semiconductor region, thereby eliminating the adverse effects of electromagnetic noise.

Furthermore, by bonding the electrode to the surface of the semiconductor region for fixed-potential connection and connecting the electrode to the fixed potential, the semiconductor layer can be connected to the fixed potential via the fixed-potential connection semiconductor region and the low-concentration impurity semiconductor layer. Thus, when the photoelectric transducer is a photodiode, the electrode can be an anode electrode or a cathode electrode.

The fact that the high concentration impurity semiconductor region has substantially no width in the width direction means that the high concentration impurity semiconductor region is substantially a line.

In the photoelectric transducer, a light-receiving area is set to accept light from outside into the low-concentration impurity semiconductor layer. The high-concentration impurity semiconductor region is essentially a line and has no substantial width in the width direction. However, if one were to deliberately express the width (thickness) of the high-concentration impurity semiconductor region in comparison to the width of the light-receiving area in the width direction, it can be said that the ratio of the width of the high-concentration impurity semiconductor region to the width of the light-receiving area in the width direction is set to be 1% or less.

The structure where the high-concentration impurity semiconductor region is essentially a line can be applied to a photoelectric transducer employing a shield structure. The photoelectric transducer employing a shield structure, for example, includes a first conductive layer formed above a low-concentration impurity semiconductor layer. The first conductive layer extends in the length direction of the high-concentration impurity semiconductor region, facing at least a portion of the high-concentration impurity semiconductor region and the thickness direction of the low-concentration impurity semiconductor layer, and is connected to a fixed potential.

For example, in a structure where the first conductive layer has a width equal to the line width of the high-concentration impurity semiconductor region in the width direction and is opposed to the entire high-concentration impurity semiconductor region in the thickness direction, electromagnetic noise entering from the outside toward the high-concentration impurity semiconductor region can be effectively blocked by the first conductive layer. Therefore, a photoelectric conversion device employing this structure can exhibit a high shielding effect against external electromagnetic noise.

In the photoelectric transducer employing the above-described shield structure, as the proportion of the high-concentration impurity semiconductor region within the light-receiving area increases, the area shaded by the first conductive layer also increases, leading to a decrease in the amount of light received. This decrease in light reception causes a reduction in the photocurrent value.

In the structure where the high concentration impurity semiconductor region is substantially a line, the area due to light blocking by the first conductive layer can be as close to 0 (zero) as possible. Therefore, the decrease in the amount of light received due to the shield structure can be suppressed and the decrease in the photocurrent value can be suppressed.

It goes without saying that the structure where the high-concentration impurity semiconductor region is essentially a line may also be applied to photoelectric transducers that do not have a shield structure. The photoelectric transducer to which the structure where the high-concentration impurity semiconductor region is essentially a line is applied may have a shield structure added externally.

When a plurality of high-concentration impurity semiconductor regions are provided, it is preferable that the high-concentration impurity semiconductor regions are set such that the sum of the areas of the high-concentration impurity semiconductor regions relative to the area of the light-receiving area is 5% or less.

A comparison is made between a photoelectric transducer employing a shield structure and a photoelectric transducer that does not employ a shield structure but otherwise has the same structure as the photoelectric transducer with the shield structure. In the photoelectric transducer employing the shield structure, to achieve an S/N ratio (signal-to-noise ratio) equivalent to that of the photoelectric transducer not employing the shield structure, it is necessary to increase the resistance value of the resistor (a resistor converting current to voltage) connected to the photoelectric transducer. Specifically, the resistance value of the resistor connected to the photoelectric transducer must be increased in proportion to the square of the inverse of the photocurrent reduction rate (the ratio of the reduction in photocurrent value of the photoelectric transducer with the shield structure to the photocurrent value of the photoelectric transducer without the shield structure).

Furthermore, as the sum of the areas of the high-concentration impurity semiconductor regions increases, the junction area between the low-concentration impurity semiconductor layer and the high-concentration impurity semiconductor regions also increases, leading to an increase in the inter-terminal capacitance of the photoelectric transducer.

The response speed of the photoelectric transducer is strongly influenced by the product of the inter-terminal capacitance of the photoelectric transducer and the resistance value of the resistor connected to the photoelectric transducer. Therefore, as shown in FIG. 17, the response speed of the photoelectric transducer employing the shield structure decreases as the proportion of the high-concentration impurity semiconductor region within the light-receiving area increases. If the proportion of the high-concentration impurity semiconductor region within the light-receiving area is 5% or less, the attenuation of the light signal intensity relative to the photoelectric transducer without the shield structure can be suppressed to −3 dB or less. Therefore, even when employing the shield structure, photoelectric transducers where the proportion of the high-concentration impurity semiconductor region in the light-receiving area is 5% or less can prevent adverse effects on the design and specifications of circuits incorporating such photoelectric transducers.

### BRIEF DESCRIPTION OF THE DRAWINGS

The various exemplary embodiments of the present invention, which will become more apparent as the description proceeds, are described in the following detailed description in conjunction with the accompanying drawings, in which:

FIG. 1 is a schematic cross-sectional view illustrating the structure of a PIN photodiode according to an embodiment of the present invention.

FIG. 2 is a plan view of the PIN photodiode shown in FIG. 1.

FIG. 3 is a cross-sectional view illustrating the structure of a PIN photodiode having a shield structure.

FIG. 4 is a plan view of the PIN photodiode shown in FIG. 3.

FIG. 5 is a cross-sectional view illustrating the structure of a PIN photodiode with another shield structure.

FIG. 6 is a plan view of the PIN photodiode shown in FIG. 5.

FIG. 7 is a cross-sectional view illustrating the structure of a PIN photodiode having yet another shield structure.

FIG. 8 is a plan view of the PIN photodiode shown in FIG. 7.

FIG. 9 is a cross-sectional view illustrating the structure of a PIN photodiode having yet another shield structure.

FIG. 10 is a plan view of the PIN photodiode shown in FIG. 9.

FIG. 11 is a cross-sectional view illustrating the structure of a PIN photodiode having yet another shield structure.

FIG. 12 is a plan view of the PIN photodiode shown in FIG. 11.

FIG. 13 is a cross-sectional view illustrating a structure of a PIN photodiode having two electrodes arranged on the surface.

FIG. 14 is a cross-sectional view illustrating another example of a structure where the two electrodes of the PIN photodiode are arranged on the surface.

FIG. 15 is a plan view of the PIN photodiode shown in FIG. 15.

FIG. 16 is a cross-sectional view illustrating the structure of a conventional PIN photodiode.

FIG. 17 is a graph showing the relationship between the ratio of the high-concentration impurity semiconductor region in the light-receiving area and the response speed of a photoelectric transducer employing a shield structure, compared to the response speed of a photoelectric transducer not employing a shield structure (corresponding response speed).

### DETAILED DESCRIPTION

### PIN Photodiode

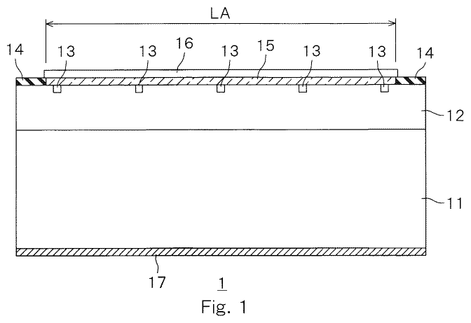

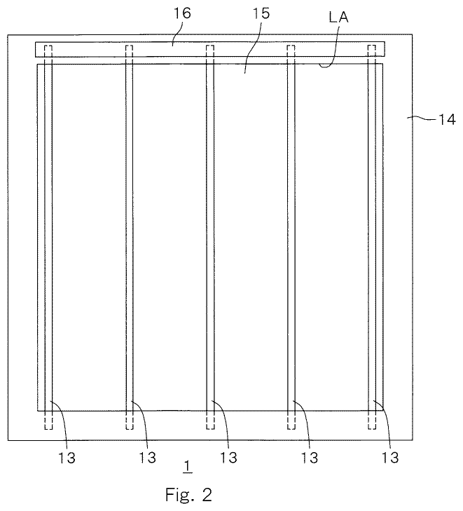

FIG. 1 is a schematic cross-sectional view illustrating the structure of a PIN photodiode 1 according to an embodiment of the present invention. FIG. 2 is a plan view of the PIN photodiode 1.

The PIN photodiode 1 includes a substrate 11 that forms its base body. The substrate 11 is made, for example, of p-type silicon (Si).

An i-layer (intrinsic layer) 12 is stacked on the substrate 11. The i-layer 12 consists of p-type silicon doped with a lower concentration of impurities (acceptors) than the substrate 11. The impurity concentration of the i-layer 12 is 1e16 cm −3 or less. The i-layer 12 is formed, for example, by epitaxial growth.

A plurality (five in the structure shown in FIGS. 1 and 2) of n+-type semiconductor regions 13 are formed on the surface layer of the i-layer 12. The n+-type semiconductor regions 13 are doped with a higher concentration of impurities than the i-layer 12. The n+-type semiconductor regions 13 are formed by diffusing impurities (donors) from the surface into the i-layer 12. As shown in FIG. 2, the n+-type semiconductor region 13 forms a linear shape extending linearly in one direction as viewed in plan view and has substantially no width in the width direction, which is orthogonal to both the length direction of the n+-type semiconductor region 13 and the thickness direction of the i-layer 12. The n+-type semiconductor region 13 extends linearly outward beyond the outer edges of the light-receiving area LA in the vertical direction (the length direction of the n+-type semiconductor region 13) as viewed in plan. Furthermore, a plurality of n+-type semiconductor regions 13 are arranged with spacing between each other in the transverse direction (the width direction of the n+-type semiconductor region 13).

An insulating film 14 is formed on the i-layer 12, surrounding the light-receiving area LA. The insulating film 14 is not formed on the light-receiving area LA. Therefore, the surface of the i-layer 12 is exposed from the insulating film 14 across the entire light-receiving area LA. That is, the insulating film 14 has an opening formed therein to expose the surface of the i-layer 12, and the light-receiving area LA is defined by the opening. The insulating film 14 is made of an insulating material such as silicon dioxide (SiO2) or silicon nitride (Si3N4).

An antireflection film 15 is formed over the surface of the i-layer 12 within the light-receiving area LA. The antireflection film 15 is made of a dielectric material having a refractive index between that of silicon and that of air, such as silicon nitride (Si3N4) or magnesium fluoride (MgF2).

An electrode 16 made of a metal or non-metallic conductive material is provided on the outer side of the light-receiving area LA when viewed from above and on one side relative to the light-receiving area LA in the vertical direction. The electrode 16 extends linearly in the transverse direction on the insulating film 14 so as to span a plurality of n+-type semiconductor regions 13. Contact holes (not shown) penetrating the insulating film 14 in the thickness direction are formed in the insulating film 14 at positions facing each n+-type semiconductor region 13 in the thickness direction. The contact holes are filled with the material of the electrode 16. The electrode 16 is connected to each n+-type semiconductor region 13 via the contact holes.

An electrode 17 made of a metal or non-metal conductive material is formed on the back surface of the substrate 11.

In the PIN photodiode 1, the electrode 16 acts as the cathode and the electrode 17 acts as the anode. To apply a reverse bias to the PIN photodiode 1, the electrode 16 (cathode) is connected to a high potential, and the electrode 17 (anode) is connected to a low potential. Furthermore, the PIN photodiode 1 is connected to an amplification circuit. The amplification circuit is, for example, a transimpedance amplifier (TIA). Electrode 17 (anode) is connected via a wiring to the input terminal of the transimpedance amplifier.

When reverse bias is applied to the PIN photodiode 1, a depletion layer spreads from the junction between the n+-type semiconductor region 13 and the i-layer 12 into the i-layer 12. When light is irradiated onto the light-receiving area LA, electrons in the valence band are excited into the conduction band, leaving holes in the valence band. As a result carriers (electrons and holes) are generated primarily in the i-layer 12. Electrons then move into the neutral region of the n+-type semiconductor region 13, while holes move into the neutral region of the substrate 11. Consequently, current is input from the electrode 16 (cathode) to the input terminal of the transimpedance amplifier, and current flows through the feedback resistor of the transimpedance amplifier. The current flowing through this feedback resistor is converted into a voltage, and the voltage is output from the transimpedance amplifier.

As described above, in the PIN photodiode 1, a plurality of linear n+-type semiconductor regions 13 are formed in the surface layer of the i-layer 12, and are arranged with spacing between them in the transverse direction. The inter-terminal capacitance of the PIN photodiode 1 is the sum of the package capacitance and the junction capacitance. The junction capacitance depends on the area where the i-layer 12 and the n+-type semiconductor region 13 are joined (the junction area). In conventional PIN photodiodes, as shown in FIG. 16, the n+-type region 103 is formed as a planar structure over a wide area. In contrast, in the PIN photodiode 1, the n+-type semiconductor region 13 is formed linearly. Therefore, the PIN photodiode 1 can achieve a smaller junction capacitance than conventional PIN photodiodes, and consequently, a smaller inter-terminal capacitance. As a result, the response speed of the PIN photodiode 1 can be improved.

A specific numerical example is provided to compare the conventional PIN photodiode (see FIG. 16) with PIN photodiode 1. Assume the light-receiving area size of the conventional PIN photodiode is 1 mm×1 mm. Furthermore, in the conventional PIN photodiode, the junction depth of the n+-region 103 (the thickness dimension of the n+-region 103 relative to the surface of the i-layer 102) is 0.4 μm, and the junction area between the i-layer 102 and the n+-region 103 is approximately 1 mm2. dimension in the thickness direction of the n+-region 103) is 0.4 μm, and the junction area between the i-layer 102 and the n+-region 103 is approximately 1 mm2. For the PIN photodiode 1, the size of the light-receiving area LA is assumed to be the same as that of the light-receiving area of the conventional PIN photodiode. Furthermore, in PIN photodiode 1, the junction depth of n+-type semiconductor region 13 is 0.4 μm. The line width (length in the transverse direction) of n+-type semiconductor region 13 within light-receiving area LA is set to 0.4 μm, and the line length (length in the vertical direction) of n+-type semiconductor region 13and the spacing between adjacent n+-type semiconductor region 13 (hereinafter referred to as the “line spacing”) is set to 30μm, the junction area between the i-layer 12 and the n+-type semiconductor region 13 becomes approximately 1/25th of the junction area of the conventional PIN photodiode. As a result, the junction capacitance of the PIN photodiode 1 becomes approximately 1/25th of the junction capacitance of the conventional PIN photodiode, enabling the inter-terminal capacitance of the PIN photodiode 1 to be made smaller than that of the conventional PIN photodiode. A PIN photodiode 1 with this design can be manufactured using the widely used 0.25 μm process rule.

The line width of the n+-type semiconductor region 13 is constrained by the process rule (process node) used to manufacture the PIN photodiode 1. For example, if a 0.6 μm process rule is used to manufacture the PIN photodiode 1, the line width of the n+-type semiconductor region 13 is considered to be at least approximately 1 μm. When a 0.25 μm process rule is used to manufacture the PIN photodiode 1, the line width of the n+-type semiconductor region 13 is considered to be at least approximately 0.4 μm. By using an even finer process rule to manufacture the PIN photodiode 1, the line width of the n+-type semiconductor region 13 can be made smaller, enabling further reduction of the junction capacitance.

When the PIN photodiode 1 is used for optical communication, the line width of the n+-type semiconductor region 13 may be set considering the communication speed of the optical communication. For example, the material for the i-layer 12 may be a compound semiconductor such as gallium arsenide (GaAs), not limited to silicon. When the i-layer 12 is composed of the compound semiconductor, it is anticipated that the PIN photodiode 1 will receive optical signals at 40 Gbps or higher. Under this assumption, considering the lateral mobility of minority carriers in the n+-type semiconductor region 13, the line width of the n+-type semiconductor region 13 is preferably 2 μm or less. To accommodate the current maximum communication speed of 100 Gbps, the line width of the n+-type semiconductor region 13 is more preferably 1 μm or less.

In addition, the size of the light-receiving area LA is generally 200 μm square or larger. Even when the PIN photodiode 1 is designed with the smallest size (200 μm square) light-receiving area LA, and the junction depth of the n+-type semiconductor region 13 is 0.4 μm, the line width is 2 μm, and the line spacing is 20 μm, the PIN photodiode 1 still achieves a junction area and junction capacitance of approximately 1/7th of that of a conventional photodiode with the same size light-receiving area. For a PIN photodiode 1 with a 200 μm square light-receiving area LA, the conversion efficiency remains essentially unchanged even when the line spacing is 20 μm or greater.

When the i-layer 12 is made of silicon, assuming reception of near-infrared light with wavelengths of 870 nm or less, and given that the absorption coefficient α of the i-layer 12 is approximately 500, when receiving a light signal, if the thickness of the i-layer 12 is 32 μm, more than 80% of that light signal can be absorbed by the i-layer 12. When layer i 12 is made of the compound semiconductor, assuming reception of light with a wavelength of 850 nm, for example, with an extinction coefficient α of 8000 or higher, when receiving an optical signal, if the thickness of the i-layer 12 is 2 μm, it can absorb 80% or more of that optical signal. Therefore, the thickness of the i-layer 12 is preferably 2 to 32 μm.

Furthermore, holes generated in the i-layer 12 due to light irradiation onto the light-receiving area LA move in the thickness direction toward substrate 11. On the other hand, electrons generated in the i-layer 12 exhibit a greater amount of movement in a direction perpendicular to the thickness direction toward the n+-type semiconductor region 13 as the line spacing (the distance between adjacent n+-type semiconductor region 13) increases. Depending on the line spacing, the amount of movement in the direction perpendicular to the thickness direction may become larger than the amount of movement in the thickness direction.

Therefore, by changing the line spacing, the average arrival time of electrons generated by light irradiation to reach the n+-type semiconductor region 13 can be adjusted, and the conversion efficiency of the PIN photodiode 1 can be adjusted. Because the line width of the n+-type semiconductor region 13 is sufficiently small relative to the line spacing, high-precision adjustment of the conversion efficiency of the PIN photodiode 1 is possible.

Furthermore, by changing the line spacing, the rising waveform of the photocurrent generated by light irradiation can also be adjusted. Since the mobility of electrons in the semiconductor is greater than that of holes (e.g., the electron mobility in a single-crystal silicon substrate is 1500 cm2/V·s, while the hole mobility is 450 cm2/V·s), increasing the line spacing to make the electron travel time closer to the hole travel time can smooth the rising and falling waveforms of the photocurrent. The sufficiently small line width of the n+-type semiconductor region 13 relative to the line spacing enables high-precision control of the photocurrent rising and falling waveforms.

Furthermore, if a non-depleted region remains in part of the i-layer 12, fractional carriers generated by photoelectric conversion also occur in that non-depleted region (majority carriers, holes, are essentially not generated), and these fractional carriers move within the non-depleted region. Even in this case, if the line spacing is sufficiently large relative to the average depth reached by light incident on the i-layer 12, the average arrival time of electrons to the n+-type semiconductor region 13 and the conversion efficiency of the PIN photodiode 1 can be adjusted.

Furthermore, when light of a wavelength penetrating the i-layer 12 and reaching the substrate 11 is incident on the light-receiving area LA, photoelectric conversion also occurs in the substrate 11, generating electrons as fractional carriers. The fractional carriers generated in the substrate 11 become a factor that slows the response speed of the PIN photodiode 1. Therefore, a blocking layer (a layer that acts as a potential barrier for electrons, which are fractional carriers) of the same type (p-type) and higher concentration than the substrate 11 may be provided between the substrate 11 and the i-layer 12 to improve the response characteristics.

In the PIN photodiode 1, since no electrode 16 (a wiring connecting n+-type semiconductor region 13 in parallel) is formed on the light-receiving area LA, interference from the electrode 16 on light irradiated onto the light-receiving area LA does not occur.

Furthermore, since no insulating film 14 is formed on the light-receiving area LA, the entire exposed area of the i-layer 12 on the light-receiving area LA can be covered by the antireflection film 15.

In a configuration where the PIN photodiode 1 is connected to a transimpedance amplifier, if the inter-terminal capacitance of the PIN photodiode 1 is small, noise near the cutoff frequency of the transimpedance amplifier can be reduced without needing to increase the feedback capacitance provided to ensure negative feedback stability in the transimpedance amplifier. Furthermore, since the feedback capacitance of the transimpedance amplifier does not need to be increased for noise reduction, the frequency bandwidth of the transimpedance amplifier is not restricted, enabling the transimpedance amplifier to achieve a wider bandwidth.

### Shield Structure 1

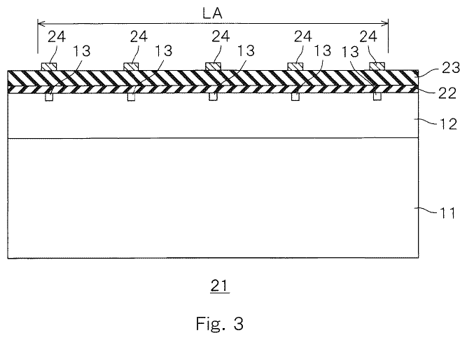

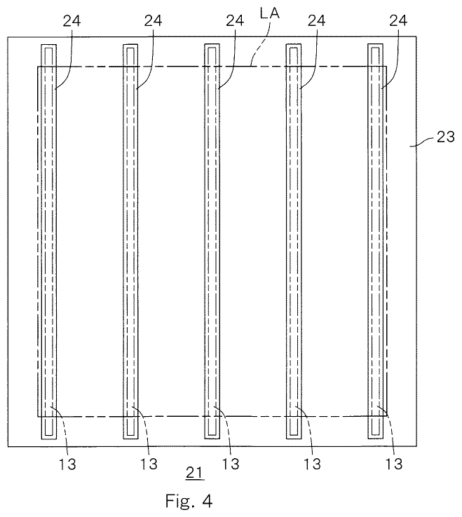

FIG. 3 is a schematic cross-sectional view illustrating the structure of a PIN photodiode 21 equipped with a shield structure. FIG. 4 is a plan view of the PIN photodiode 21. Referring to FIGS. 3 and 4, portions corresponding to those shown in FIGS. 1 and 2, respectively, are denoted by the same reference numerals as those portions. Hereinafter, descriptions of portions assigned the same reference numerals are omitted.

The PIN photodiode 21 is fabricated on the substrate 11 forming the base body, together with other semiconductor devices such as CMOS (Complementary Metal Oxide Semiconductor) transistors. Therefore, on the i-layer 12, interlayer films 22, 23, included in the multilayer wiring structure for other semiconductor devices, are stacked in this order from the i-layer 12 side. The interlayer films 22, 23 also remain on the i-layer 12 within the light-receiving area LA without being removed. The interlayer films 22, 23 are made of insulating materials such as silicon dioxide or silicon nitride.

A first conductive layer 24 is provided on the interlayer film 23, corresponding to each n+-type semiconductor region 13. The first conductive layer 24 extends in the vertical direction above the n+-type semiconductor region 13. The first conductive layer 24 is opposed to the entire n+-type semiconductor region 13 in the thickness direction. The first conductive layer 24 is made of a metal or a non-metal conductive material (e.g., polysilicon). On the outside of the light-receiving region LA, for example, another interlayer film is further stacked on the interlayer film 23, and a wiring (fixed-potential wiring) connected to a fixed potential such as ground potential or power supply potential is provided on the other interlayer film. The first conductive layer 24 is connected to the wiring through a via penetrating the other interlayer film in the thickness direction, thereby connecting it to the fixed potential.

With this configuration, even if electromagnetic noise enters from the outside toward the n+-type semiconductor region 13, that electromagnetic noise is blocked by the first conductive layer 24. Therefore, it is possible to prevent external electromagnetic noise from reaching the n+-type semiconductor region 13 and eliminate adverse effects caused by electromagnetic noise.

In the PIN photodiode 21, the first conductive layer 24 was described as being opposed to the entire underlying n+-type semiconductor region 13 in the thickness direction. However, even if the first conductive layer 24 is opposed to only a portion of the underlying n+-type semiconductor region 13 in the thickness direction, it will still provide some degree of electromagnetic noise shielding effect.

Although the first conductive layer 24 was described as being connected to the fixed-potential wiring outside the light-receiving area LA, the first conductive layer 24 may also be connected to the fixed-potential wiring inside the light-receiving area LA. Furthermore, a semiconductor region containing impurities at a high concentration may be formed in the surface layer portion of the i-layer 12, and the first conductive layer 24 may be connected to the fixed potential via this semiconductor region.

Furthermore, the first conductive layer 24 may be divided into two parts in the vertical direction, with these divided parts spaced apart from each other (a gap being formed between the two divided parts) in the vertical direction, and each divided part may be connected to the fixed potential outside the light-receiving area LA. The first conductive layer 24 may be divided into three or more parts in the vertical direction, with these divided parts spaced apart from each other in the vertical direction, and each divided part connected to the fixed potential either outside or inside the light-receiving area LA. That is, regardless of whether the first conductive layer 24 is divided into a plurality of parts in the vertical direction, as long as the first conductive layer 24 can be connected to the fixed potential, the method of connection is not limited.

### Shield Structure 2

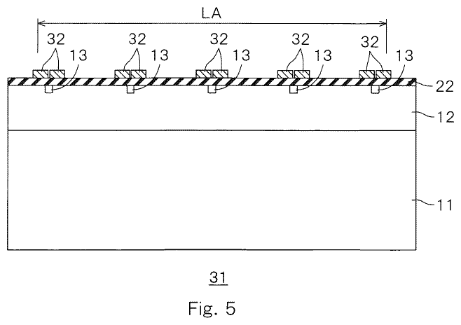

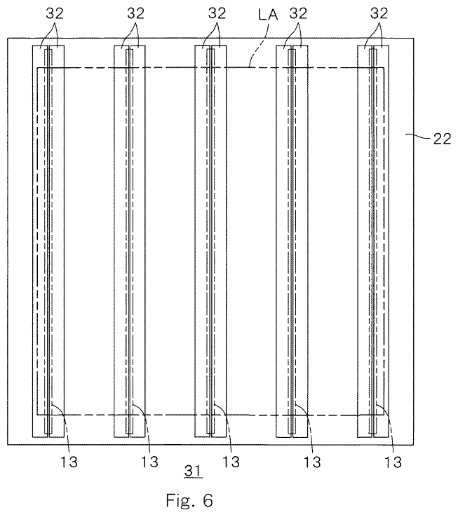

FIG. 5 is a schematic cross-sectional view illustrating the structure of a PIN photodiode 31 having another shield structure. FIG. 6 is a plan view of the PIN photodiode 31. Referring to FIGS. 5 and 6, portions corresponding to those shown in FIGS. 3 and 4, respectively, are denoted by the same reference numerals as those portions. Hereinafter, descriptions of portions assigned the same reference numerals are omitted.

The PIN photodiode 31, like the PIN photodiode 21, is fabricated on the substrate 11 that forms the base body, together with other semiconductor devices. In the PIN photodiode 31, an interlayer film 22 is formed on the i-layer 12 within the light-receiving area LA.

A plurality of second conductive layers 32 are provided on the interlayer film 22, corresponding to each n+-type semiconductor region 13. Each of the a plurality of second conductive layers 32 extends in the vertical direction above its corresponding n+-type semiconductor region 13. The plurality of second conductive layers 32 are opposed in the thickness direction to different portions of the n+-type semiconductor region 13. In the structure shown in FIGS. 5 and 6, two second conductive layers 32 are provided above each n+-type semiconductor region 13. The two second conductive layers 32 are opposed in the thickness direction to the one edge and the other edge of the n+-type semiconductor region 13 in the transverse direction, respectively. The second conductive layers 32 are opposed to the n+-type semiconductor region 13 for the entire length of the vertical direction. The second conductive layer 32 is made of a metal or a non-metallic conductive material (e.g., polysilicon). On the outside of the light-receiving area LA, for example, another interlayer film is further stacked on the interlayer film 22, and a wiring (fixed-potential wiring) connected to a fixed potential, such as ground potential or power supply potential, is provided on the other interlayer film. The second conductive layer 32 is connected to the fixed potential by being connected to the fixed-potential wiring through a via penetrating the interlayer film in the thickness direction.

In this configuration as well, when electromagnetic noise enters from the outside toward the n+-type semiconductor region 13, that electromagnetic noise is blocked by the second conductive layer 32. Therefore, it is possible to prevent external electromagnetic noise from reaching the n+-type semiconductor region 13 and eliminate adverse effects caused by electromagnetic noise.

Although the second conductive layer 32 was described as being connected to the fixed-potential wiring outside the light-receiving area LA, the second conductive layer 32 may also be connected to the fixed-potential wiring inside the light-receiving area LA. Furthermore, a semiconductor region containing impurities at a high concentration may be formed in the surface layer portion of the i-layer 12, and the second conductive layer 32 may be connected to the fixed potential via this semiconductor region.

Furthermore, the second conductive layer 32 may be divided into two parts in the vertical direction, with these divided parts spaced apart from each other (a gap being formed between the two divided parts) in the vertical direction, and each divided part may be connected to the fixed potential outside the light-receiving area LA. The second conductive layer 32 may be divided into three or more parts in the vertical direction, with these divided parts spaced apart from each other in the vertical direction, and each divided part connected to the fixed potential either outside or inside the light-receiving area LA. That is, regardless of whether the second conductive layer 32 is divided into a plurality of parts in the vertical direction, as long as the second conductive layer 32 can be connected to the fixed potential, the method of connection is not limited.

Since the second conductive layer 32 is opposed to a portion of the n+-type semiconductor region 13 in the thickness direction, it can also be considered an example of the “first conductive layer” of the present invention.

### Shield Structure 3

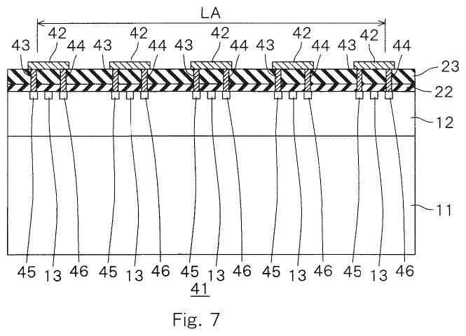

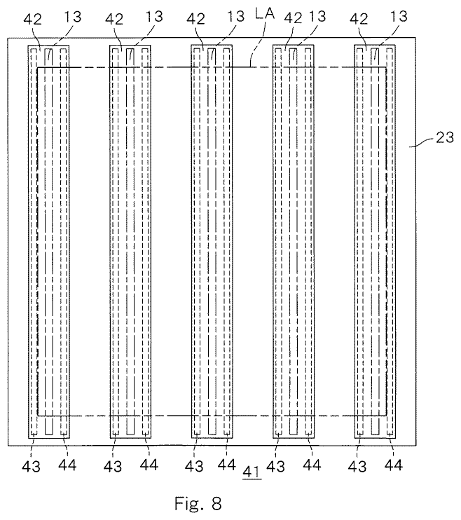

FIG. 7 is a schematic cross-sectional view illustrating the structure of a PIN photodiode 41 equipped with yet another shield structure. FIG. 8 is a plan view of this PIN photodiode 41. Referring to FIGS. 7 and 8, portions corresponding to those shown in FIGS. 3 and 4, respectively, are denoted by the same reference numerals as those portions. Hereinafter, descriptions of portions assigned the same reference numerals are omitted.

The PIN photodiode 41, like the PIN photodiode 21, is fabricated on the substrate 11 forming the base body together with other semiconductor elements. In the PIN photodiode 41, a first conductive layer 42 is provided on the interlayer film 23, corresponding to each n+-type semiconductor region 13. The first conductive layer 42 extends in the vertical direction above the n+-type semiconductor region 13. The first conductive layer 42 is opposed to the entire n+-type semiconductor region 13 in the thickness direction. Furthermore, the first conductive layer 42 is formed with a larger dimension of the transverse direction than the n+-type semiconductor region 13. Consequently, one edge and the other edge of the first conductive layer 42 in the transverse direction are opposed to the i-layer 12 on one side and the other side relative to the n+-type semiconductor region 13 in the transverse direction, respectively. The first conductive layer 42 is made of a metal or a non-metal conductive material (e.g., polysilicon). The first conductive layer 42 is connected to a wiring (fixed-potential wiring) having a fixed potential, such as a ground potential or a power supply potential, outside the light-receiving area LA.

Furthermore, vias 43, 44 are formed between the one end and the other end of the first conductive layer 42 in the transverse direction and the i-layer 12, respectively. The vias 43, 44 are made of a metal such as tungsten. The vias 43, 44 penetrate the interlayer films 22, 23. The vias 43, 44 extend in the vertical direction for a length greater than the vertical length of the n+-type semiconductor region 13. The upper ends of the vias 43, 44 are connected to the first conductive layer 42. The lower ends of the vias 43, 44 are connected to the i-layer 12. In the i-layer 12, contact regions 45, 46, doped with a higher acceptor concentration than the surrounding area, are provided at the portions where the vias 43, 44 connect. In other words, on the surface layer of the i-layer 12, p-type contact regions 45, 46, each doped with acceptors at a higher concentration than their surroundings, are provided on one side and the other side of the n+-type semiconductor region 13, spaced apart in the transverse direction. The contact regions 45, 46 extend in the vertical direction, and the lower ends of the vias 43, 44 are joined to the contact regions 45, 46, respectively. Thus, the vias 43, 44 form ohmic contacts with the i-layer 12.

With this configuration, even if electromagnetic noise enters the n+-type semiconductor region 13 from the outside in the thickness direction, the electromagnetic noise is blocked by the first conductive layer 42. Furthermore, even if electromagnetic noise enters from the outside toward the n+-type semiconductor region 13 in a direction intersecting the thickness direction, that electromagnetic noise is blocked by the first conductive layer 42 or the vias 43, 44. Therefore, it is possible to prevent external electromagnetic noise from reaching the n+-type semiconductor region 13 and eliminate adverse effects caused by electromagnetic noise.

Although the first conductive layer 42 was described as being connected to the fixed-potential wiring outside the light-receiving area LA, the first conductive layer 42 may also be connected to the fixed-potential wiring inside the light-receiving area LA. Furthermore, a semiconductor region containing impurities at a high concentration may be formed in the surface layer of the i-layer 12, and the first conductive layer 42 may be connected to the fixed potential via this semiconductor region.

Furthermore, the first conductive layer 42 may be divided into two parts in the vertical direction, with these divided parts spaced apart from each other (a gap being formed between the two divided parts) in the vertical direction, and each divided part may be connected to a fixed potential outside the light-receiving area LA. The first conductive layer 42 may be divided into three or more parts in the vertical direction, with these divided parts spaced apart from each other in the vertical direction, and each divided part connected to the fixed potential either outside or inside the light-receiving area LA. That is, regardless of whether the first conductive layer 42 is divided into a plurality of parts in the vertical direction, as long as the first conductive layer 42 can be connected to the fixed potential, the method of connection is not restricted.

Furthermore, the vias 43, 44 may each be divided into a plurality of parts in the vertical direction, with these divided parts spaced apart from each other in the vertical direction, and gaps may exist between mutually adjacent divided parts.

### Shield Structure 4

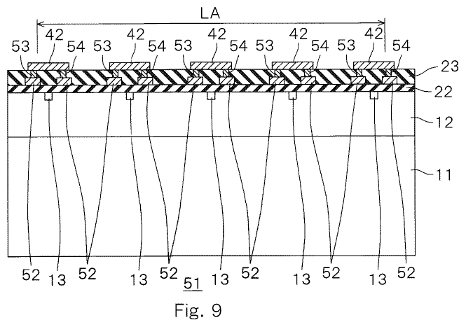

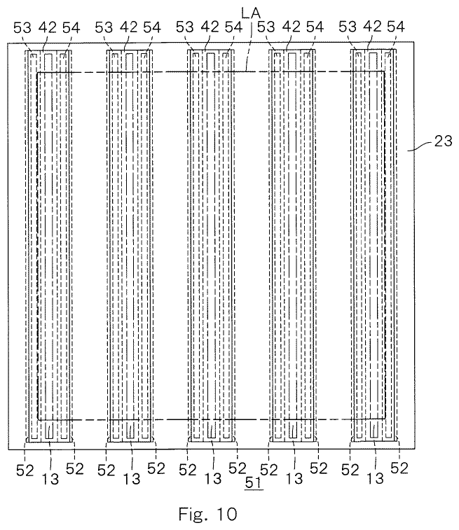

FIG. 9 is a schematic cross-sectional view illustrating the structure of a PIN photodiode 51 having another shield structure. FIG. 10 is a plan view of the PIN photodiode 51. Referring to FIGS. 9 and 10, portions corresponding to those shown in FIGS. 7 and 8, respectively, are denoted by the same reference numerals as those portions. Hereinafter, descriptions of potions assigned the same reference numerals are omitted.

The PIN photodiode 51, like the PIN photodiode 21, is fabricated on the substrate 11 that forms the base body together with other semiconductor elements. In the PIN photodiode 51, a plurality of second conductive layers 52 are formed on the interlayer film 22, corresponding to each n+-type semiconductor region 13. Each of the second conductive layers 52 extend in the vertical direction above the respective n+-type semiconductor regions 13. Each of the second conductive layer 52 may or may not be opposed to a different portion of the n+-type semiconductor region 13 in the thickness direction. In the structure shown in FIGS. 9 and 10, two second conductive layers 52 are provided above each n+-type semiconductor region 13, and the two second conductive layers 52 do not be opposed to the n+-type semiconductor region 13 in the thickness direction. The second conductive layer 52 comprises a metal or a non-metal conductive material (e.g., polysilicon).

Furthermore, in the PIN photodiode 51, the one edge and the other edge of the first conductive layer 42 on the interlayer film 23 are opposed in thickness-direction to the second conductive layer 52. Furthermore, vias 53, 54 are formed between each of the one edge and the other edge of the first conductive layer 42 in the transverse direction and the second conductive layer 52, respectively. The vias 53, 54 are made of a metal such as tungsten. The vias 53, 54 penetrate the interlayer film 23. The upper ends of the vias 53, 54 are connected to the first conductive layer 42, and their lower ends are connected to the second conductive layer 52. Furthermore, the vias 53, 54 extend in the vertical direction for a length greater than the vertical length of the n+-type semiconductor region 13.

This configuration ensures that even if electromagnetic noise enters the n+-type semiconductor region 13 from the outside in the thickness direction, the electromagnetic noise is blocked by the first conductive layer 42 or the second conductive layer 52. Furthermore, even if electromagnetic noise enters from the outside toward the n+-type semiconductor region 13 in the direction intersecting the thickness direction, that electromagnetic noise is blocked by the first conductive layer 42, the second conductive layer 52, or the vias 53, 54. Therefore, it is possible to prevent external electromagnetic noise from reaching the n+-type semiconductor region 13 and eliminate adverse effects caused by electromagnetic noise.

Moreover, the vias 53, 54 may each be divided into a plurality of parts in the vertical direction, with these divided parts spaced apart vertically from each other in the vertical direction, and gaps may exist between mutually adjacent divided parts.

Furthermore, while the first conductive layer 42 may be connected to the fixed potential, the second conductive layer 52 may be connected to the fixed potential either outside or inside the light-receiving area LA.

### Shield Structure 5

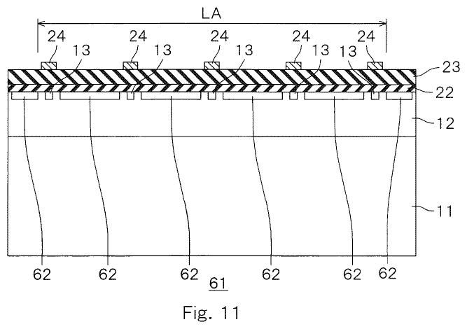

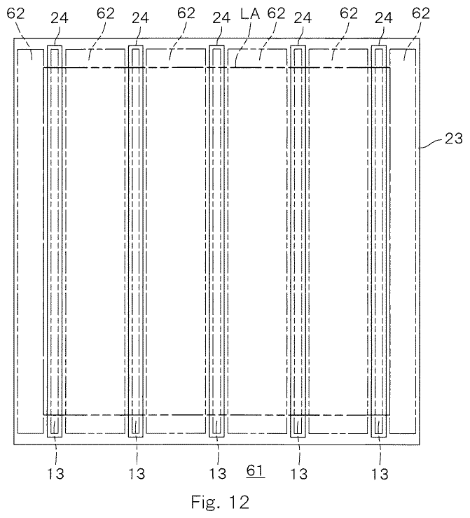

FIG. 11 is a schematic cross-sectional view illustrating the structure of a PIN photodiode 61 having another shield structure. FIG. 12 is a plan view of the PIN photodiode 61. Referring to FIGS. 11 and 12, portions corresponding to those shown in FIGS. 3 and 4, respectively, are denoted by the same reference numerals as those portions. Hereinafter, descriptions of portions assigned the same reference numerals are omitted.

The PIN photodiode 61, like the PIN photodiode 21, is fabricated on the substrate 11 forming the base body together with other semiconductor devices. In the PIN photodiode 61, a plurality (six in the structure shown in FIGS. 11 and 12) of p+-type semiconductor regions 62 are provided in the surface layer portion of the i-layer 12. The p+-type semiconductor regions 62 are formed by diffusing impurities (acceptors) into the i-layer 12 from its surface and are doped with a higher impurity concentration than the i-layer 12. The p+-type semiconductor regions 62 form a band extending linearly in the vertical direction, spaced apart laterally from the n+-type semiconductor regions 13. Outside the light-receiving area LA, for example, a wiring is provided on the interlayer film 22. The p+-type semiconductor region 62 is connected via the wiring to a fixed potential, such as ground potential or power supply potential, so that a reverse bias is applied between mutually adjacent n+-type semiconductor regions 13 and p(+) type semiconductor regions 62.

With this configuration, even if electromagnetic noise enters from the outside toward the n+-type semiconductor region 13, the electromagnetic noise is blocked by the first conductive layer 24. Furthermore, even if electromagnetic noise enters from the outside between mutually adjacent n+-type semiconductor regions 13, that electromagnetic noise is blocked by the p+-type semiconductor region 62. Therefore, it is possible to prevent external electromagnetic noise from reaching the n+-type semiconductor regions 13 and eliminate adverse effects caused by electromagnetic noise.

Although the p+-type semiconductor region 62 was described as being connected to the fixed potential via the wiring outside the light-receiving area LA, the p+-type semiconductor region 62 may also be connected to the fixed potential via a wiring inside the light-receiving area LA. Furthermore, a p+-type semiconductor region extending in the direction perpendicular to the vertical direction may be formed on the surface layer of the i-layer 12, and the p+-type semiconductor region 62 may be connected to the fixed potential via the p+-type semiconductor region extending in the direction perpendicular to the vertical direction.

Furthermore, the p+-type semiconductor region 62 may be divided into two parts in the vertical direction, with these divided parts spaced apart from each other (a gap being formed between the two divided parts) in the vertical direction, and each divided part may be connected to the fixed potential outside the light-receiving area LA. The p+-type semiconductor region 62 may be divided into three or more parts in the vertical direction, with these divided parts spaced apart from each other in the vertical direction, and each divided part connected to the fixed potential either outside or inside the light-receiving area LA. That is, regardless of whether the p+-type semiconductor region 62 is divided into a plurality of parts in the vertical direction, as long as the p+-type semiconductor region 62 can be connected to the fixed potential, the method of connection is not limited.

### Surface Electrode 1

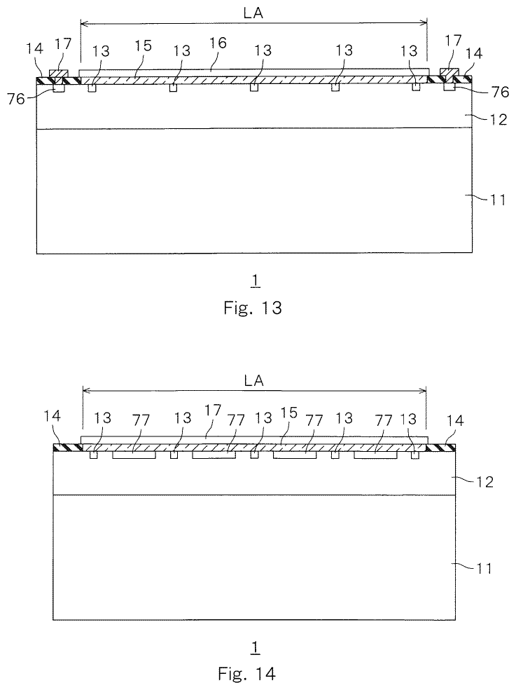

FIG. 13 is a schematic cross-sectional view illustrating the structure of the PIN photodiode 1 with the electrode 17 positioned on the surface.

In the structure shown in FIG. 1, electrode 17 was formed on the back surface of substrate 11. However, as shown in FIG. 13, electrode 17 may also be formed on the surface of PIN photodiode 1. In the PIN photodiode 1 shown in FIG. 13, a p+-type contact region 76 is formed annularly surrounding the light-receiving area LA by diffusing impurities (acceptors) from the surface into the peripheral region of the surface layer of the i-layer 12. An insulating film 14 surrounding the light-receiving area LA has annular contact holes formed in the portion facing the contact region 76, penetrating the insulating film 14 in the thickness direction. The contact holes are filled with the material of the electrode 17. Electrode 17 is bonded to contact region 76 via the contact hole. Thus, electrode 17 makes ohmic contact with the i-layer 12.

Furthermore, since the p+-type contact region 76 is formed in a ring surrounding the light-receiving area LA, the spread of the depletion layer in the vertical and transverse directions from within the light-receiving area LA can be suppressed, thereby suppressing the adverse effect of the spread of the depletion layer on the peripheral circuit.

### Surface Electrode 2

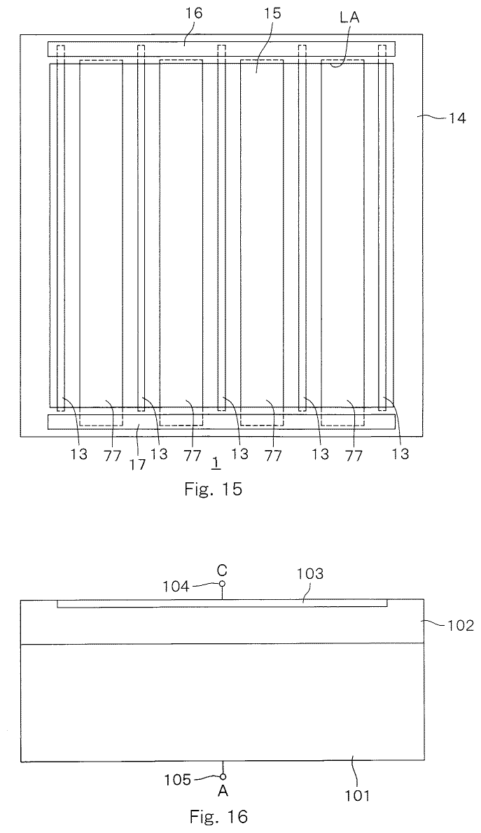

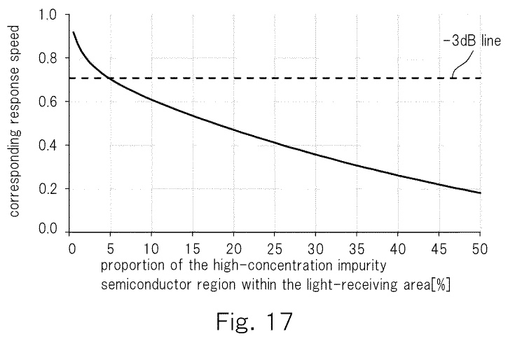

FIG. 14 is a cross-sectional view illustrating another example of a structure where the electrode 17 of the PIN photodiode 1 is arranged on the surface. FIG. 15 is a plan view of the structure shown in FIG. 14.

In the configuration shown in FIG. 13, the p+-type contact region 76 is formed at the periphery of the surface layer portion of the i-layer 12. In contrast, in the configuration shown in FIGS. 14 and 15, a p+-type contact region 77 is provided between mutually adjacent linear n+-type semiconductor regions 13 within the surface layer portion of the i-layer 12. The contact region 77 is formed by diffusing impurities (acceptors) into the i-layer 12 from its surface and is doped with a higher impurity concentration than the substrate 11 and the i-layer 12. Furthermore, the contact region 77 extends linearly in the vertical direction as viewed from above, extending straight outward beyond both the one edge and the other edge of the light-receiving area LA in the vertical direction.

Furthermore, an electrode 17 made of a metal or non-metal conductive material is formed on the insulating film 14, on the side opposite electrode 16 in the vertical direction relative to the light-receiving area LA and outside the light-receiving area LA when viewed in plan. Electrode 17 extends linearly in the transverse direction, spanning a plurality of contact regions 77. Contact holes (not shown) penetrating the insulating film 14 in the thickness direction are formed in the insulating film 14 in the portions where each contact region 77 and electrode 17 oppose each other in the thickness direction. The contact holes are filled with the material of electrode 17. Electrode 17 is bonded (ohmic contact) to each contact area 77 via the contact holes.

### Modified Example

For example, the i-layer 12 may be not only p-type silicon doped with a lower concentration of impurities than the substrate 11, but also an intrinsic semiconductor (single crystal silicon) containing no impurities.

In the PIN photodiode 51 shown in FIGS. 9 and 10, the vias 53, 54 may be omitted, and the first conductive layer 42 and the second conductive layer 52 may be connected to a fixed potential outside the light receiving area LA. In this configuration as well, when electromagnetic noise enters the n+-type semiconductor region 13 from the outside in the thickness direction, that electromagnetic noise can be blocked by the first conductive layer 42 or the second conductive layer 52. Furthermore, even if electromagnetic noise enters from the outside toward the n+-type semiconductor region 13 in the direction intersecting the thickness direction, the electromagnetic noise can be blocked by the first conductive layer 42 or the second conductive layer 52. Therefore, it is possible to prevent external electromagnetic noise from reaching the n+-type semiconductor region 13 and eliminate adverse effects caused by electromagnetic noise.

In the structure shown in FIG. 13, the contact area 76 and electrode 17 may be formed in a shape that surrounds the light-receiving area LA on three sides. The contact area 76 and electrode 17 may be formed in an L-shaped configuration extending in the vertical and transverse directions outside the light-receiving area LA. The contact area 76 and electrode 17 may be formed as a band extending linearly on both the vertical and transverse sides relative to the light-receiving area LA. The contact area 76 and electrode 17 may be formed as a band extending linearly in the vertical or transverse direction outside the light-receiving area LA.

The aforementioned embodiment described a configuration where the n+-type semiconductor region 13 forms a linear shape extending straight in one direction when viewed in plan. However, the n+-type semiconductor region 13, as long as it forms a linelike shape, need not be strictly straight. For example, it may have a shape that is curved or bent in part (such as an arc shape or a roughly V-shaped shape), it may be serpentine, or it may be zigzagged.

Furthermore, at least one n+-type semiconductor region 13 may be provided.

A configuration where a plurality of n+-type semiconductor regions 13 intersect each other may be adopted. For example, a plurality of n+-type semiconductor regions 13 may be formed in a grid-like or mesh-like pattern.

Furthermore, while the case where the first conductivity type is p-type and the second conductivity type is n-type has been described, the first conductivity type may be n-type and the second conductivity type may be p-type.

As required, detailed embodiments of the present invention are disclosed herein; however, it is to be understood that the disclosed embodiments are merely exemplary of the invention, which may be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure.

When it is apparent that the illustrative embodiments of the invention disclosed herein fulfill the objectives stated above, it will be appreciated that numerous modifications and other embodiments may be devised by one of ordinary skill in the art. Accordingly, it will be understood that the appended claims are intended to cover all such modifications and embodiments, which come within the spirit and scope of the present invention.

1. A photoelectric transducer comprising:
a first conductivity type semiconductor layer;
a low-concentration impurity semiconductor layer formed on the first conductivity type semiconductor layer and having a lower impurity concentration than the semiconductor layer; and
a high-concentration impurity semiconductor region, formed in the surface layer of the low-concentration impurity semiconductor layer, and having a second conductivity type different from the first conductivity type and a higher impurity concentration than the low-concentration impurity semiconductor layer,
wherein the high-concentration impurity semiconductor region is a linelike shape and has substantially no width in a width direction perpendicular to both the length direction of the high-concentration impurity semiconductor region and the thickness direction of the low-concentration impurity semiconductor layer.

2. The photoelectric transducer according to claim 1, wherein
the photoelectric transducer is provided with a light-receiving area configured to receive light from outside into the low-concentration impurity semiconductor layer, and
the width of the high-concentration impurity semiconductor region is set such that the ratio of the width of the high-concentration impurity semiconductor region to the width of the light-receiving area in the width direction is 1% or less.

3. The photoelectric transducer according to claim 1, further comprising:
a first conductive layer formed above the low-concentration impurity semiconductor layer,
wherein the first conductive layer extends in the length direction, opposes at least a portion of the high-concentration impurity semiconductor region in the thickness direction, and is connected to a fixed potential.

4. The photoelectric transducer according to claim 3, further comprising:
a plurality of second conductive layers formed above the low-concentration impurity semiconductor layer,
wherein the plurality of second conductive layers extend in the length direction, respectively, facing different portions of the high-concentration impurity semiconductor region in the thickness direction, and are connected to the fixed potential.

5. The photoelectric transducer according to claim 3, further comprising:
an interlayer film formed between the low-concentration impurity semiconductor layer and the first conductive layer; and
two vias extending in the length direction, penetrating the interlayer film in the thickness direction, and connecting the first conductive layer and the low-concentration impurity semiconductor layer, wherein
a first conductive type contact region, having a higher impurity concentration than the low-concentration impurity semiconductor layer, is formed on the surface layer portion of the low-concentration impurity semiconductor layer, spaced apart from the high-concentration impurity semiconductor region on one side and the other side in the width direction,
The two vias are respectively connected to the contact regions on one side and the other side in the width direction relative to the high-concentration impurity semiconductor region.

6. The photoelectric transducer according to claim 1, further comprising:
a first conductivity type fixed-potential connection semiconductor region formed in the surface layer of the low-concentration impurity semiconductor layer,
wherein the fixed-potential connection semiconductor region is spaced apart in the width direction from the high-concentration impurity semiconductor region, extends in the length direction, and is connected to the fixed potential.
